(19) United States
(12) Patent Application Publication
(10) Pub. No.: US 2010/0310174 A1
(43) Pub. Date: Dec. 9, 2010

(54) EFFICIENT INCREMENTAL CODING OF PROBABILITY DISTRIBUTIONS FOR IMAGE FEATURE DESCRIPTORS

(75) Inventor: Yuriy Reznik, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/794,271

(22) Filed: Jun. 4, 2010

Related U.S. Application Data
(60) Provisional application No. 61/184,641, filed on Jun. 5, 2009.

(51) Int. Cl. G06K 9/54; H03M 7/00

(52) U.S. Cl. 382/190; 341/107

(57) ABSTRACT

A method and device for incremental encoding of a type of a sequence is provided. A sequence of symbols is obtained where each symbol is defined within a set of symbols. The type of sequence may be, for example, an empirical probability distribution of symbols in a sequence of symbols. Each obtained symbol may be identified in the sequence. Each symbol in the sequence of symbols is then arithmetically coded using only previous occurrences of the same symbol in the sequence of symbols as a context to generate an incremental code. The incremental codes for the symbols in the set of symbols are then concatenated or combined to generate a complete code representative of the type of the sequence of symbols.

### CLAIM OF PRIORITY UNDER 35 U.S.C. §119

The present Application for Patent claims priority to U.S. Provisional Application No. 61/184,641 entitled “Incremental Coding of Distributions” filed Jun. 5, 2009, assigned to the assignee hereof and hereby expressly incorporated by reference herein.

### BACKGROUND

1. Field

The following description generally relates to object detection methodologies and, more particularly, to efficiently coding of probability distributions for local feature descriptors.

2. Background

Various applications may benefit from having a machine or processor that is capable of identifying objects in a visual representation (e.g., an image or picture). The fields of computer vision and/or object detection attempt to provide techniques and/or algorithms that permit identifying objects or features in an image, where an object or feature may be characterized by descriptors identifying one or more keypoints. Generally, this may involve identifying points of interest (also called keypoints) in an image for the purpose of feature identification, image retrieval, and/or object recognition. Preferably, the keypoints may be selected and/or processed such that they are invariant to image scale changes and/or rotation and provide robust matching across a substantial range of distortions, changes in point of view, and/or noise and change in illumination. Further, in order to be well suited for tasks such as image retrieval and object recognition, the feature descriptors may preferably be distinctive in the sense that a single feature can be correctly matched with high probability against a large database of features from many images.

After the keypoints in an image are detected and located, they may be identified or described by using various descriptors. For example, descriptors may descriptions of the visual features of the content in images, such as shape, color, texture, rotation, and/or motion, among other image characteristics. The individual features corresponding to the keypoints and represented by the descriptors are then matched to a database of features from known objects. Therefore, a correspondence searching system can be separated into three modules: keypoint detector, feature descriptor, and correspondence locator. In these three logical modules, the descriptor's construction complexity and dimensionality have direct and significant impact on the performance of the feature matching system.

A number of algorithms, such as Scale Invariant Feature Transform (SIFT), have been developed to first compute such keypoints and then proceed to extract one or more localized features around the keypoints. This is a first step towards detection of particular objects in an image and/or classifying the queried object based on the local features. SIFT is one approach for detecting and extracting local feature descriptors that are reasonably invariant to changes in illumination, image noise, rotation, scaling, and small changes in viewpoint. The feature detection stages for SIFT include: (a) scale-space extrema detection, (b) keypoint localization, (c) orientation assignment, and/or (d) generation of keypoint descriptors. Other alternative algorithms for generating descriptors include Speed Up Robust Features (SURF), Gradient Location and Orientation Histogram (GLOH), Local Energy based Shape Histogram (LESH), Compressed Histogram of Gradients (CHoG), among others.

Such feature descriptors are increasingly finding applications in real-time object recognition, 3D reconstruction, panorama stitching, robotic mapping, video tracking, and similar tasks. Depending on the application, transmission and/or storage of feature descriptors (or equivalent) can limit the speed of computation of object detection and/or the size of image databases. In the context of mobile devices (e.g., camera phones, mobile phones, etc.) or distributed camera networks, significant communication and power resources may be spent in transmitting information (e.g., including an image and/or image descriptors) between nodes. Feature descriptor compression is hence important for reduction in storage, latency, and transmission.

Therefore, there is a need for a way to efficiently represent and/or compress feature descriptors.

### SUMMARY

The following presents a simplified summary of one or more embodiments in order to provide a basic understanding of some embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to one feature, a method for incremental encoding of a type of a sequence is provided. A sequence of symbols is obtained or received, where each symbol is defined within a set of symbols. In one example, the set of symbols includes a plurality of two or more symbols. For instance, the sequence of symbols may be representative of a set of gradients for a patch around a keypoint for an image object. Each symbol in the sequence may then be identified or parsed. In one example, each symbol may be defined by one or more bits. Each symbol in the sequence of symbols is then arithmetically coded using only previous occurrences of the same symbol in the sequence of symbols as a context to generate an incremental code. Arithmetically coding each symbol may be performed separately for each symbol for the set of symbols. For instance, distinct arithmetic coders may be assigned to each symbol in the set of symbols and all occurrences of the same symbol in the sequence are coded by the same arithmetic coder. Therefore, the number of distinct arithmetic coders are equal to a number of symbols in the set of symbols. In one example, the arithmetic coders may be adaptive arithmetic coders. Each arithmetic coder may estimate probability of occurrence of the next symbol as

$$\frac{{k}_{i} + \frac{1}{2}}{{k}_{i} + 1} ,$$

where kᵢ is the number of previous occurrences of the same symbol in the sequence of symbols.

The incremental codes for the symbols in the set of symbols are then concatenated, combined, and/or multiplexed to generate a complete code representative of the type of the sequence of symbols. The type of sequence may be an empirical probability distribution of symbols in the sequence of symbols. Concatenating the incremental code for each symbol in the set of symbols is performed after all symbols in the sequence have been arithmetically coded by a plurality of symbol-specific arithmetic coders. The complete code may be subsequently stored and/or transmitted as part of a feature descriptor.

According to one implementation, this encoding method may be implemented by an encoding device that includes a receiver interface, a symbol identifier, a plurality of arithmetic coders and/or a multiplexer. The receiver interface may obtain or receive a sequence of symbols, where each symbol is defined within a set of symbols. The symbol identifier may be adapted to identify each symbol in the sequence. Each arithmetic coder may correspond to a different symbol in the set of symbols and may be adapted to arithmetically code its corresponding symbol in the sequence of symbols using only previous occurrences of the same symbol in the sequence of symbols as a context to generate an incremental code. The multiplexer may be adapted to concatenate, combine, and/or multiplex the incremental codes for the symbols in the set of symbols to generate a complete code representative of the type of the sequence of symbols.

According to another feature, a method for decoding a type of a sequence is provided. A complete code representative of a type of a sequence is received or obtained. The set of symbols may include a plurality of two or more symbols. In one example, the sequence may be representative of a set of gradients for a patch around a keypoint for an image object. For instance, complete code may be received as part of a feature descriptor. The complete code is then parsed to obtain a plurality of incremental codes, each incremental code being representative of a symbol in a set of symbols. Each incremental code may also be representative of a frequency of occurrence of the corresponding symbol within the sequence. Each incremental code may then be arithmetically decoded to obtain the type of the sequence. The type of sequence may be an empirical probability distribution of symbols in the sequence. Arithmetically decoding each symbol may be performed separately for each symbol for the set of symbols. For instance, distinct arithmetic decoders may be assigned to each symbol in the set of symbols and all occurrences of the same symbol are decoded by the same arithmetic decoder. Consequently, the number of distinct arithmetic decoders may be equal to a number of symbols in the set of symbols. In one example, the arithmetic decoders are adaptive arithmetic decoders. Each incremental code may be generated by an arithmetic coder that estimates probability of occurrence of the next symbol as

$$\frac{{k}_{i} + \frac{1}{2}}{{k}_{i} + 1} ,$$

where kᵢ is the number of previous occurrences of the same symbol.

In one implementation, the decoding method may be implemented by a decoding device that includes a receiver, a parser, and/or a plurality of arithmetic decoders. The receiver may receive a complete code representative of a type of a sequence. The parser then parses the complete code to obtain a plurality of incremental codes, each incremental code representative of a symbol in a set of symbols. Each arithmetic decoder may correspond to a different symbol in the set of symbols and may be adapted to decode a corresponding incremental code to obtain the type of the sequence.

### BRIEF DESCRIPTION OF THE DRAWINGS

Various features, nature, and advantages may become apparent from the detailed description set forth below when taken in conjunction with the drawings in which like reference characters identify correspondingly throughout.

FIG. 1 is a block diagram illustrating the functional stages for performing object recognition on a queried image.

FIG. 2 illustrates a difference of Gaussian (DoG) pyramid constructed by computing the difference of any two consecutive Gaussian-blurred images in the Gaussian pyramid.

FIG. 3 illustrates a more detailed view of how a keypoint may be detected.

FIG. 4 illustrates how a gradient distributions and orientation histograms may be obtained.

FIG. 5 illustrates one example for the construction and selection of types and indexes.

FIG. 6 illustrates a plot of a Rate versus Distortion (R-D) boundary achievable by type coding.

FIG. 7 illustrates several example type lattices created for ternary histograms.

FIG. 8 is a block diagram illustrating the incremental coding of a type of a sequence for a binary set of symbols.

FIG. 9 is a block diagram illustrating the incremental coding of a type of a sequence including an m-ary set of symbols.

FIG. 10 is a block diagram illustrating decoding of an incrementally coded type of a sequence having an m-ary set of symbols.

FIG. 11 is a block diagram of an exemplary encoding device for incremental encoding of a type of a sequence.

FIG. 12 illustrates an exemplary method for incremental encoding of a type of a sequence.

FIG. 13 is a block diagram illustrating an exemplary mobile device adapted to perform incremental probability distribution encoding.

FIG. 14 is a block diagram illustrating an exemplary decoder.

FIG. 15 illustrates an exemplary method for incremental decoding to obtain a type of a sequence.

FIG. 16 is a block diagram illustrating an example of an image matching device.

### DETAILED DESCRIPTION

Various embodiments are now described with reference to the drawings, wherein like reference numerals are used to refer to like elements throughout. In the following description, for purposes of explanation, numerous specific details are set forth in order to provide a thorough understanding of one or more embodiments. It may be evident, however, that such embodiment(s) may be practiced without these specific details. In other instances, well-known structures and devices are shown in block diagram form in order to facilitate describing one or more embodiments.

### Overview

A compact and/or efficient representation for feature descriptors is provided by efficiently incrementally coding frequencies of symbols within a symbol sequence. In general, an arbitrary sequence of samples/symbols of a given length is to be encoded. Rather than encoding the sequence itself, the sequence is coded by arithmetically and/or incrementally coding each occurrence of a symbol in the sequence with previous occurrences of the same symbol in the sequence. This process is repeated to all symbols in a set of symbols. Ultimately, the different incremental codes for the different symbols are combined to obtain a complete code representative of a type of the sequence of symbols. A type of sequence may be an empirical probability distribution of symbols in the sequence of symbols.

### Exemplary Generation of Descriptors

For purposes of illustration, various examples discussed herein may use a Scale Invariant Feature Transform (SIFT) algorithm and/or a Compressed Histogram of Gradients (CHoG) algorithm (or variations thereof) to provide some context to the examples. However, it should be clear that alternative algorithms for generating descriptors, including Speed Up Robust Features (SURF), Gradient Location and Orientation Histogram (GLOH), Local Energy based Shape Histogram (LESH), among others, may also benefit for the features described herein.

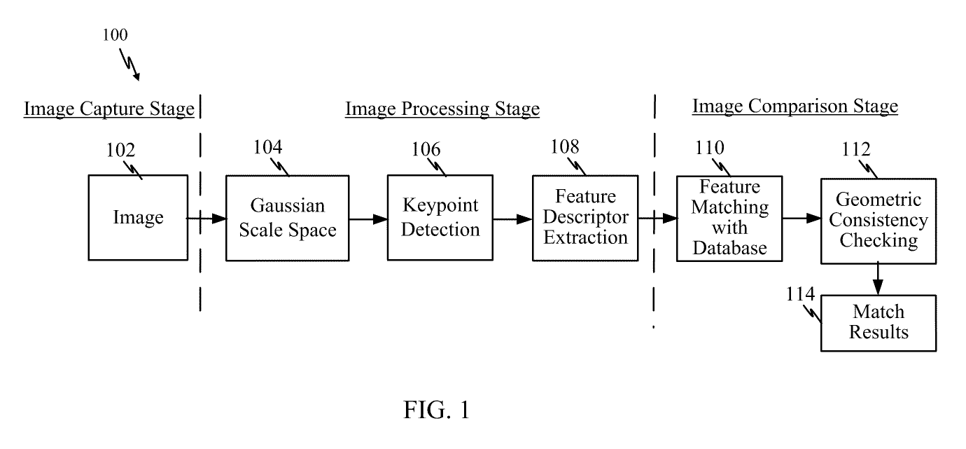

FIG. 1 is a block diagram illustrating the functional stages for performing object recognition on a queried image. At an image capture stage, an image 102 of interest may be captured. The captured image 102 is then processed by generating a corresponding Gaussian scale space 104, performing keypoint detection 106, and performing feature descriptor extraction 108. At the end of the image processing stage, a plurality of descriptors (e.g., feature descriptors) have been generated that identify one or more objects or features within the captured image 102. At an image comparison stage, these descriptors are used to perform feature matching 110 (e.g., by comparing keypoints and/or other characteristics) with a database of known descriptors. Geometric consistency checking 112 is then performed on keypoint matches to ascertain correct feature matches and provide match results 114.

Image Capturing: In one example, the image 102 may be captured in a digital format that may define the image I(x, y) as a plurality of pixels with corresponding color, illumination, and/or other characteristics.

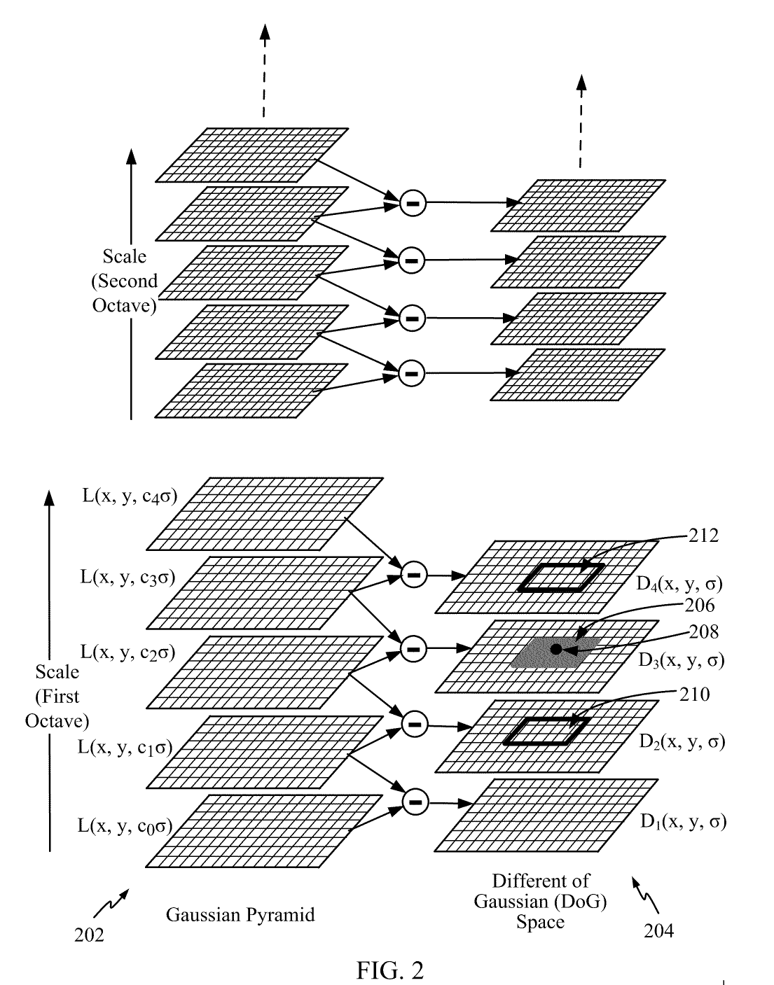

Gaussian Scale Space: FIG. 2 illustrates a difference of Gaussian (DoG) pyramid 204 constructed by computing the difference of any two consecutive Gaussian-blurred images in the Gaussian pyramid 202. The input image I(x, y) is gradually Gaussian blurred to construct the Gaussian pyramid 202. Gaussian blurring generally involves convolving the original image I(x, y) with the Gaussian blur function G(x, y, cσ) at scale cσ such that the Gaussian blurred function L(x, y, cσ) is defined as L(x, y, cσ)=G(x, y, cσ)*I(x, y). Here, G is a Gaussian kernel, cσ denotes the standard deviation of the Gaussian function that is used for blurring the image I(x, y). As c, is varied (c₀<c₁<c₂<c₃<c₄), the standard deviation cσ varies and a gradual blurring is obtained. Sigma σ is the base scale variable (essentially the width of the Gaussian kernel). When the initial image I(x, y) is incrementally convolved with Gaussians G to produce the blurred images L, the blurred images L are separated by the constant factor c in the scale space.

In the DoG space 204, D(x, y, a)=L(x, y, cₙσ)−L(x, y, cₙ₋₁σ). A DoG image D(x, y, σ) is the difference between two adjacent Gaussian blurred images L at scales cₙσ and cₙ₋₁σ. The scale of the D(x, y, σ) lies somewhere between cₙσ and cₙ₋₁σ. As the number of Gaussian-blurred images L increase and the approximation provided for the Gaussian pyramid 202 approaches a continuous space, the two scales also approach into one scale. The convolved images L may be grouped by octave, where an octave corresponds to a doubling of the value of the standard deviation σ. Moreover, the values of the multipliers k (e.g., c₀<c₁<c₂<c₃<c₄), are selected such that a fixed number of convolved images L are obtained per octave. Then, the DoG images D may be obtained from adjacent Gaussian-blurred images L per octave. After each octave, the Gaussian image is down-sampled by a factor of 2 and then the process is repeated.

Keypoint Detection: The DoG space 204 may then be used to identify keypoints for the image I(x, y). Keypoint detection seeks to determine whether the local region or patch around a particular sample point or pixel in the image is a potentially interesting patch (geometrically speaking). Generally, local maxima and/or local minima in the DoG space 204 are identified and the locations of these maxima and minima are used as keypoint locations in the DoG space 204. In the example illustrated in FIG. 2, a keypoint 208 has been identified with a patch 206. Finding the local maxima and minima (also known as local extrema detection) may be achieved by comparing each pixel (e.g., the pixel for keypoint 208) in the DoG space 204 to its eight neighboring pixels at the same scale and to the nine neighboring pixels (in adjacent patches 210 and 212) in each of the neighboring scales on the two sides, for a total of 26 pixels (9×2+8=26). If the pixel value for the keypoint 206 is a maximum or a minimum among all 26 compared pixels in the patches 206, 210, and 208, then it is selected as a keypoint. The keypoints may be further processed such that their location is identified more accurately and some of the keypoints, such as the low contrast key points and edge key points may be discarded.

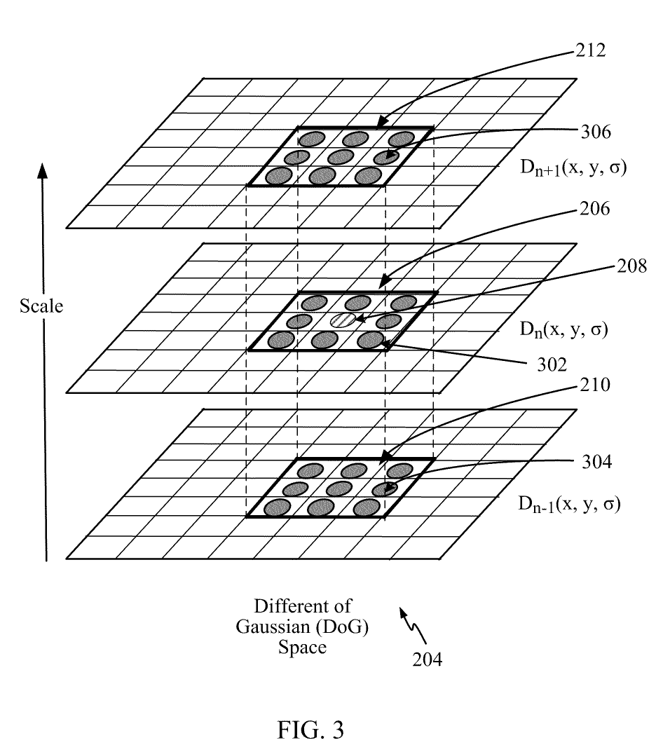

FIG. 3 illustrates a more detailed view of how a keypoint may be detected. Here, each of the patches 206, 210, and 212 include a 3×3 pixel region. A pixel of interest (e.g., keypoint 208) is compared to its eight neighboring pixels 302 at the same scale (e.g., patch 206) and to the nine neighboring pixels 304 and 306 in adjacent patches 210 and 212 in each of the neighboring scales on the two sides of the keypoint 208.

Descriptor Extraction: Each keypoint may be assigned one or more orientations, or directions, based on the directions of the local image gradient. By assigning a consistent orientation to each keypoint based on local image properties, the keypoint descriptor can be represented relative to this orientation and therefore achieve invariance to image rotation. Magnitude and direction calculations may be performed for every pixel in the neighboring region around the keypoint 208 in the Gaussian-blurred image L and/or at the keypoint scale. The magnitude of the gradient for the keypoint 208 located at (x, y) may be represented as m(x, y) and the orientation or direction of the gradient for the keypoint at (x, y) may be represented as Γ(x, y). The scale of the keypoint is used to select the Gaussian smoothed image, L, with the closest scale to the scale of the keypoint 208, so that all computations are performed in a scale-invariant manner. For each image sample, L(x, y), at this scale, the gradient magnitude, m(x, y), and orientation, Γ(x, y), are computed using pixel differences. For example the magnitude m(x,y) may be computed as:

$$m ( x , y ) = \sqrt{{( L ( x + 1 , y ) - L ( x - 1 , y ) )}^{2} + {( L ( x , y + 1 ) - L ( x , y - 1 ) )}^{2}} . \qquad ( Equation 1 )$$

The direction or orientation Γ(x, y) may be calculated as:

$$Γ ( x , y ) = arctan [ \frac{( L ( x , y + 1 ) L ( x , y - 1 )}{( L ( x + 1 , y ) - L ( x - 1 , y )} ] . \qquad ( Equation 2 )$$

Here, L(x, y) is a sample of the Gaussian-blurred image L(x, y, σ), at scale σ which is also the scale of the keypoint.

The gradients for the keypoint may be calculated consistently either for the plane in the Gaussian pyramid that lies above, at a higher scale, than the plane of the keypoint in the DoG space or in a plane of the Gaussian pyramid that lies below, at a lower scale, than the keypoint. Either way, for each keypoint, the gradients are calculated all at one same scale in a rectangular area (e.g., patch) surrounding the keypoint. Moreover, the frequency of an image signal is reflected in the scale of the Gaussian-blurred image. Yet, SIFT simply uses gradient values at all pixels in the patch (e.g., rectangular area). A patch is defined around the keypoint; sub-blocks are defined within the block; samples are defined within the sub-blocks and this structure remains the same for all keypoints even when the scales of the keypoints are different. Therefore, while the frequency of an image signal changes with successive application of Gaussian smoothing filters in the same octave, the keypoints identified at different scales may be sampled with the same number of samples irrespective of the change in the frequency of the image signal, which is represented by the scale.

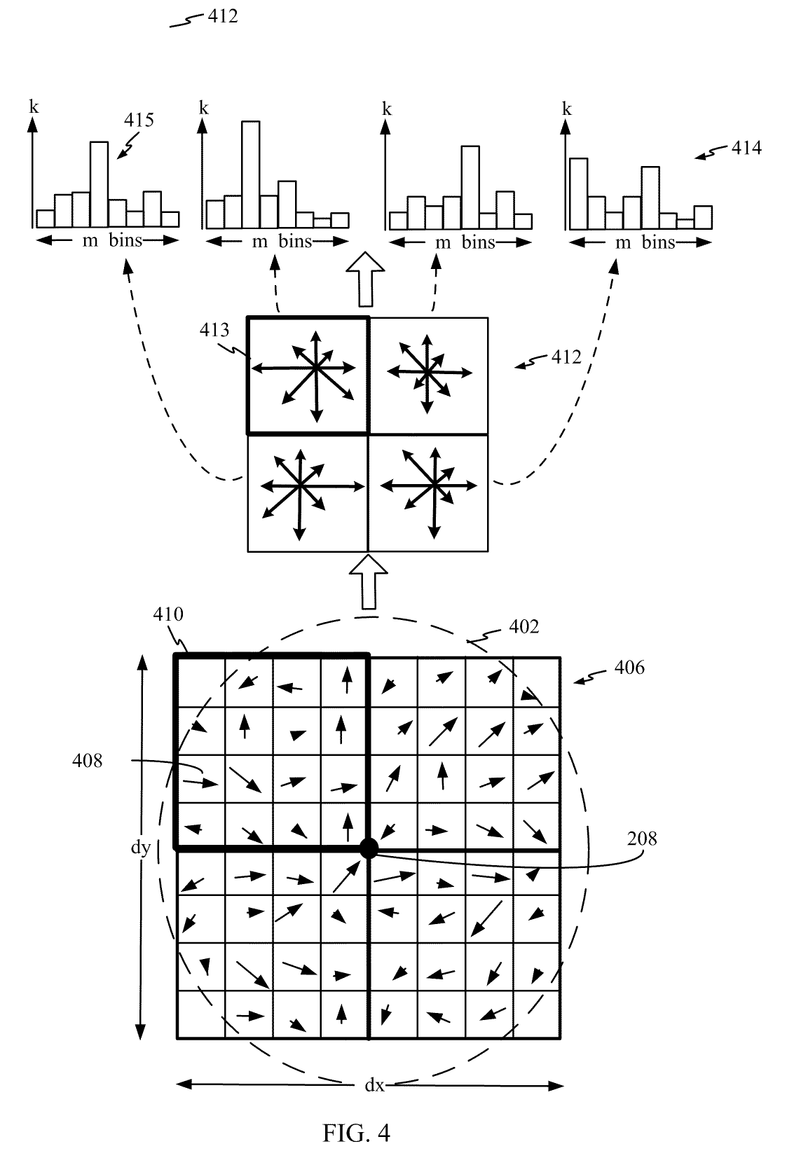

To characterize a keypoint orientation, a vector of gradient orientations may be generated (in SIFT) in the neighborhood of the keypoint (using the Gaussian image at the closest scale to the keypoint's scale). However, keypoint orientation may also be represented by a gradient orientation histogram (see FIG. 4) by using, for example, Compressed Histogram of Gradients (CHoG). The contribution of each neighboring pixel may be weighted by the gradient magnitude and a Gaussian window. Peaks in the histogram correspond to dominant orientations. All the properties of the keypoint may be measured relative to the keypoint orientation, this provides invariance to rotation.

In one example, the distribution of the Gaussian-weighted gradients may be computed for each block where each block is 2 sub-blocks by 2 sub-blocks for a total of 4 sub-blocks. To compute the distribution of the Gaussian-weighted gradients, an orientation histogram with several bins is formed with each bin covering a part of the area around the keypoint. For example, the orientation histogram may have 36 bins, each bin covering 10 degrees of the 360 degree range of orientations. Alternatively, the histogram may have 8 bins each covering 45 degrees of the 360 degree range. It should be clear that the histogram coding techniques described herein may be applicable to histograms of any number of bins. Note that other techniques may also be used that ultimately generate a histogram.

FIG. 4 illustrates how a gradient distributions and orientation histograms may be obtained. Here, a two-dimensional gradient distribution (dx, dy) (e.g., block 406) is converted to a one-dimensional distribution (e.g., histogram 414). The keypoint 208 is located at a center of the patch 406 (also called a cell or region) that surrounds the keypoint 208. The gradients that are pre-computed for each level of the pyramid are shown as small arrows at each sample location 408. As shown, 4×4 regions of samples 408 form a sub-block 410 and 2×2 regions of sub-blocks form the block 406. The block 406 may also be referred to as a descriptor window. The Gaussian weighting function is shown with the circle 402 and is used to assign a weight to the magnitude of each sample point 408. The weight in the circular window 402 falls off smoothly. The purpose of the Gaussian window 402 is to avoid sudden changes in the descriptor with small changes in position of the window and to give less emphasis to gradients that are far from the center of the descriptor. A 2×2=4 array of orientation histograms 412 is obtained from the 2×2 sub-blocks with 8 orientations in each bin of the histogram resulting in a (2×2)×8=32 dimensional feature descriptor vector. For example, orientation histograms 413 and 415 may correspond to the gradient distribution for sub-block 410. However, using a 4×4 array of histograms with 8 orientations in each histogram (8-bin histograms), resulting in a (4×4)×8=128 dimensional feature descriptor vector for each keypoint may yield a better result. Note that other types of quantization bin constellations (e.g., with different Voronoi cell structures) may also be used to obtain gradient distributions.

As used herein, a histogram is a mapping kᵢ that counts the number of observations, sample, or occurrences (e.g., gradients) that fall into various disjoint categories known as bins. The graph of a histogram is merely one way to represent a histogram. Thus, if k is the total number of observations, samples, or occurrences and m is the total number of bins, the frequencies in histogram kᵢ satisfy the following condition:

$$n = {\sum }_{i = 1}^{m} {k}_{i} \qquad ( Equation 3 )$$

where Σ is the summation operator.

Each sample added to the histograms 412 may be weighted by its gradient magnitude within a Gaussian-weighted circular window 402 with a standard deviation that is 1.5 times the scale of the keypoint. Peaks in the resulting orientation histogram 414 correspond to dominant directions of local gradients. The highest peak in the histogram is detected and then any other local peak that is within a certain percentage, such as 80%, of the highest peak is used to also create a keypoint with that orientation. Therefore, for locations with multiple peaks of similar magnitude, there will be multiple keypoints created at the same location and scale but different orientations.

The histograms from the sub-blocks may be concatenated to obtain a feature descriptor vector for the keypoint. If the gradients in 8-bin histograms from 16 sub-blocks are used, a 128 dimensional feature descriptor vector may result.

In this manner a descriptor may be obtained for each keypoint, where such descriptor may be characterized by a location (x, y), an orientation, and a descriptor of the distributions of the Gaussian-weighted gradients. Note that an image may be characterized by one or more keypoint descriptors (also referred to as image descriptors).

In some exemplary applications, an image may be obtained and/or captured by a mobile device and object recognition may be performed on the captured image or part of the captured image. According to a first option, the captured image may be sent by the mobile device to a server where it may be processed (e.g., to obtain one or more descriptors) and/or compared to a plurality of images (e.g., one or more descriptors for the plurality of images) to obtain a match (e.g., identification of the captured image or object therein). However, in this option the whole captured image is sent, which may be undesirable due to its size. In a second option, the mobile device processes the image (e.g., perform feature extraction on the image) to obtain one or more image descriptors and sends the descriptors to a server for image and/or object identification. Because the keypoint descriptors for the image are sent, rather than the image, this may take less transmission time so long as the keypoint descriptors for the image are smaller than the image itself. Thus, compressing the size of the keypoint descriptors is highly desirable.

In order to minimize the size of a keypoint descriptor, it may beneficial to compress the descriptor of the distribution of gradients. Since the descriptor of the distribution of gradients is represented by histogram, efficient coding techniques for histograms are described herein.

### Efficient Coding of Histograms

In order to efficiently represent and/or compress feature descriptors, the descriptor of the distributions (e.g., orientation histograms) may be more efficiently represented. Thus, one or more methods or techniques for efficiently coding of histograms are herein provided. Note that these methods or techniques may be implemented with any type of histogram implementation to efficiently (or even optimally) code a histogram in a compressed form. Efficiently coding of a histogram is a distinct problem not addressed by traditional encoding techniques. Traditional encoding techniques have focused on efficiently encoding a sequence of values. Because sequence information is not used in a histogram, efficiently encoding a histogram is a different problem.

As a first step, consideration is given to the optimal (smallest size or length) coding of a histogram. Information theory may be applied to obtain a maximum length for lossless and/or lossy encoding of a histogram.

As noted above, for a particular patch (e.g., often referred to as a cell or region), the distribution of gradients in the patch may be represented as a histogram. A histogram may be represented as an alphabet A having a length of m symbols (2≦m≦∞), where each symbol is associated with a bin in the histogram. Therefore, the histogram has a total number of m bins. For example, each symbol (bin) in the alphabet A may correspond to a gradient/orientation from a set of defined gradients/orientations. Here, n may represent the total number of observations, samples, or occurrences (gradient samples in a cell, patch, or region) and k represents the number of observations, samples, or occurrences in a particular bin (e.g., k₁ is number of gradient samples in first bin . . . kₘ is the number of gradient samples in mth bin), such that

$$n = {\sum }_{i = 1 … m} {k}_{i} .$$

That is, the sum of all gradient samples in the histogram bins is equal to the total number of gradient samples in the patch. Because a histogram may represent a probability distribution for a first distribution of gradient samples within a cell, patch, or region, it is possible that different cells, patches, or regions having a second distribution (different from the first distribution) of gradient samples may nonetheless have the same histogram.

Let now P denote an m-ary probability distribution. [p₁, . . . , pₘ]. The entropy H(P) of this distribution defined as:

$$H ( P ) = - {\sum }_{i = 1}^{m} {p}_{i} log {p}_{i} . \qquad ( Equation 4 )$$

The relative entropy D(P∥Q) between two known distributions P and Q is given by

$$D ( P \vert \vert Q ) = {\sum }_{i = 1}^{m} {p}_{i} log \frac{{p}_{i}}{{q}_{i}} . \qquad ( Equation 5 )$$

For a given sample w of gradient distributions, lets assumer that the number of times each gradient value appears is given by kᵢ (for i=1, . . . m). The probability P(w) of the sample w is thus given by:

$$P ( w ) = {\prod }_{i = 1}^{m} {p}_{i} {k}^{{k}_{i}} \qquad ( Equation 6 )$$

where π is the product operator.
For example, in the case of a cell or patch, the probability P(w) is going to be a probability of a particular cell or patch.

However, Equation 6 assumes that the distribution P is known. In the case where the source distribution is unknown, as may be the case with typical gradients in a patch, the probability of a sample w may be given by the Krichecvsky-Trofimov (KT) estimate:

$${P}_{KT} ( w ) = Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} , \qquad ( Equation 7 )$$

where Γ is the Gamma function such that Γ(n)=(n−1)!.

If the sample w is to be encoded using the KT-estimate of its probability, the length L of such encoding (under actual distribution P) satisfies:

$${L}_{KT} ( w , P ) = - {\sum }_{w} P ( m ) log {P}_{KT} ( w ) \sim nH ( P ) + \frac{m - 1}{2} log n . \qquad ( Equation 8 )$$

Equation 8 provides the maximum code length for lossless encoding of a histogram. The redundancy of KT-estimator-based code is given by:

$${R}_{KT} ( n ) \sim \frac{m - 1}{2} log n , \qquad ( Equation 9 )$$

which does not depend on the actual source distribution. This implies that such code is universal. Thus, the KT-estimator provides a close approximation of actual probability P so long as the sample w used is sufficiently long.

Note that the KT-estimator is only one way to compute probabilities for distributions. For example, a maximum likelihood (ML) estimator may also be used.

Also, when coding a histogram, it is assumed that both the encoder and decoder know the total number of samples n in the histogram and the number of bins m for the histogram. Thus, this information need not be encoded. Therefore, the encoding is focused on the number of samples for each of the m bins.

Coding of Types: Rather than transmitting the histogram itself as part of the keypoint (or image) descriptor, a compressed form of the histogram may be used. To accomplish this, histograms may be represented by types. Generally, a type is a compressed representation of a histogram (e.g., where the type represents the shape of the histogram rather than full histogram). The type t of a sample w may be defined as:

$$t ( w ) = [ \frac{{k}_{1}}{n} , … , \frac{{k}_{n}}{n} ] \qquad ( Equation 10 )$$

such that the type t(w) represents a set of frequencies of its symbols (e.g., the frequencies of gradient distributions kᵢ). A type can also be understood as an estimate of the true distribution of the source that produced the sample. Thus, encoding and transmission of type t(w) is equivalent to encoding and transmission of the shape of the distribution as it can be estimated based on a particular sample w.

However, traditionally encoding techniques have focused on efficiently encoding a sequence of values. Because sequence information is not used in a histogram, efficiently encoding a histogram is a different problem. Assuming the number of bins is known to the encoder and decoder, encoding of histograms involves encoding the total number of points (e.g., gradients) and the points per bin.

Sample-to-Type Mapping: Hereafter, the goal is to figure out how to encode type t(w) efficiently. Notice that any given type t may be defined as:

$$t = [ \frac{{k}_{1}}{n} , … , \frac{{k}_{n}}{n} : {\sum }_{i = 1}^{m} {k}_{i} = n ] . \qquad ( Equation 11 )$$

where kₗ to kₘ denote the number of possible types t given the total number of samples n.
Therefore, the total number of possible sequences with type t can be given by:

$$ξ ( t ) = ( \begin{matrix}n \\ {k}_{1} , … , {k}_{m}\end{matrix} ) \qquad ( Equation 12 )$$

where ξ(t) is total number of possible arrangements of symbols with a population t.

The total number of possible types is essentially the number of all integers kₗ, . . . , kₘ such that kₗ+ . . . +kₘ=n, and it is given by the multiset coefficient:

$$M ( m , n ) = ( \begin{matrix}n + m - 1 \\ m - 1\end{matrix} ) \qquad ( Equation 13 )$$

Distribution of Types: The probability of occurrence of any sample w of type t may be denoted by P(t). Since there are ξ(t) such possible samples, and they all have the same probabilities, then:

$$\begin{matrix}P ( t ) = ξ ( t ) P ( w \text{:} t ( w ) = t ) \\ = ( \begin{matrix}n \\ {k}_{1} , … , {k}_{m}\end{matrix} ) {p}_{1}^{{k}_{1}} … {p}_{m}^{{k}_{m}}\end{matrix} \qquad ( Equation 14 )$$

This density P(t) may be referred to as a distribution of types. It is clearly a multinomial distribution, with maximum (mode) at:

$$P ( {t}^{*} ) = P ( t : {k}_{i} = {np}_{i} ) = ( \begin{matrix}n \\ {np}_{1} , … , {np}_{m}\end{matrix} ) {p}_{1}^{{np}_{1}} … {p}_{m}^{{np}_{1}} . \qquad ( Equation 15 )$$

The entropy of distribution of types is subsequently (by concentration property):

$$\begin{matrix}H ( P ( t ) ) = - {\sum }_{i} P ( t ) log P ( t ) \sim log ( P ( {t}^{*} ) ) \\ = \frac{m - 1}{2} log n + O ( 1 ) .\end{matrix} \qquad ( Equation 16 )$$

Universal Coding and Lossless Coding of Types: Given a sample w of length n, the task of universal encoder is to design a code f(w) (or equivalently, its induced distribution P_{f}(w)), such that its worst-case average redundancy:

$$\begin{matrix}R * ( n ) = {sup}_{P} [ {\sum }_{\vert w \vert = n} P ( w ) \vert f ( w ) \vert - nH ( P ) ] & ( Equation 17 ) \\ \geq {sup}_{P} {\sum }_{\vert w \vert = n} P ( w ) log \frac{P ( w )}{{P}_{f} ( w )} = n {sup}_{P} D ( P \vert \vert {P}_{f} ) & ( Equation 18 )\end{matrix}$$

is minimal. Equations 17 and 18 describe the problem being addressed by universal coding, which given a sequence, a code length is sought where the difference between an average code length and n*H(P) is minimal for all possible input distributions. That is, the minimum worst-case code length is sought without knowing the distribution beforehand.

Since probabilities of samples of the same type are the same, and code induced distribution P_{f}(w) is expected to retain this property, P_{f}(w) can be defined as:

$${P}_{f} ( w ) = \frac{{P}_{f} ( w : t ( w ) = t )}{ξ ( t )} , \qquad ( Equation 19 )$$

where P_{f}(t) is the probability of a type t(w) and ξ(t) is the total number of sequences within the same type t(w). The probability P_{f} of a code assigned to a type t(w) can thus be defined as:

P_{f}(t)=ξ(t)P_{f}(w:t(w)=t) (Equation 20)

is code-induced distribution of types.

By plugging such decomposition in Equation 18 and changing the summation to go over types (instead of individual samples), the average redundancy R*(n) may be defined as:

$$\begin{matrix}R * ( n ) \geq su {p}_{P} {\sum }_{\vert w ∈ {A}^{n}} P ( w ) log \frac{P ( w )}{{P}_{f} ( w )} & ( Equation 21.1 ) \\ = {sup}_{P} [ {\sum }_{t} {\sum }_{w \text{:} t ( w ) = t} P ( w ) log \frac{P ( t )}{{P}_{f} ( t )} ] & ( Equation 21.2 ) \\ = {sup}_{p} [ {\sum }_{t} P ( t ) log \frac{P ( t )}{{P}_{f} ( t )} ] & ( Equation 21.3 ) \\ = {sup}_{P} D ( P ( t ) \vert \vert {P}_{f} ( t ) ) , & ( Equation 21.4 )\end{matrix}$$

where “sup” is the supremum operator, where a value is a supremum with respect to a set if it is at least as large as any element of that set. These equations mean that the problem of coding of types is equivalent to the problem of minimum redundancy universal coding.

Consequently, the problem of lossless coding of types can be asymptotically optimally solved by using KT-estimated distribution of types:

$$\begin{matrix}{P}_{KT} ( t ) = ξ ( t ) {P}_{KT} ( w : t ( w ) = t ) & ( Equation 22.1 ) \\ = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} & ( Equation 22.2 )\end{matrix}$$

Based on this Equation 22.2, it becomes clear that types with near uniform populations fall in the valleys of the estimated density, while types with singular populations (ones with zero counts) become its peaks.

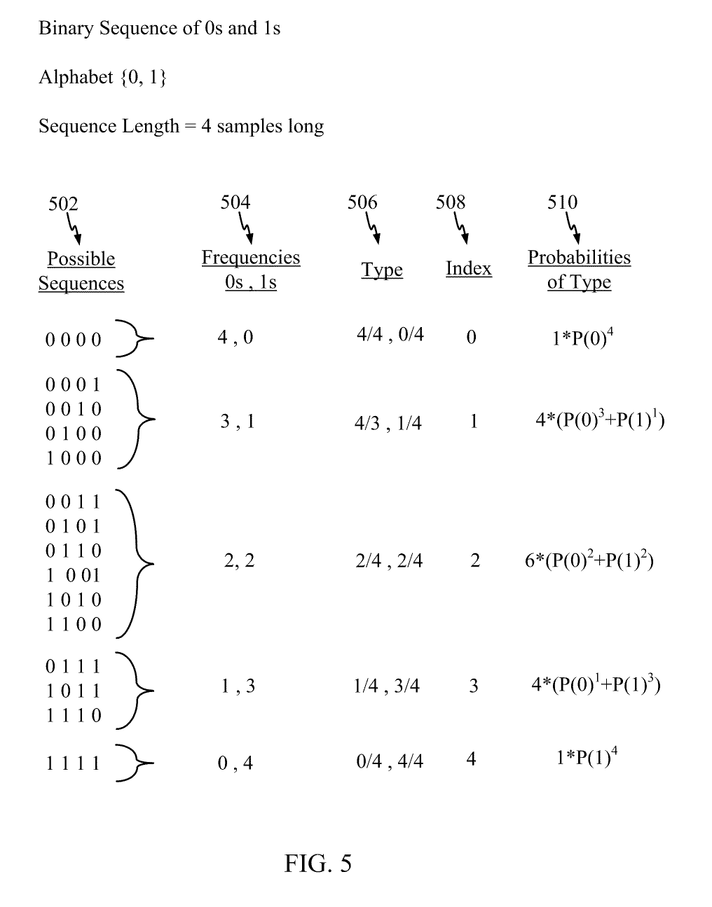

FIG. 5 illustrates one example for the construction and selection of types and indexes. In this example, sample sequence has a length of four samples (n=4), with two possible symbols (m=2) (e.g., alphabet of symbols 0 and 1). All possible sequences 502 have been arranged herein showing their distributions 504 for the two symbols (0, 1). From this distribution 504, it can be seen that each distribution 504 may be assigned a Type 506 so that the possible sequences 502 can be represented by five (5) types. Note that each type may represent a histogram. Each Type 506 may be assigned an Index 508, which may be used for transmission or storage of a histogram. Note that the sum of the Probability of Type 510 will be equal to 1.

Design of Codes: Since size of type distribution

$$M ( m , n ) = ( \begin{matrix}n + m - 1 \\ m - 1\end{matrix} ) \qquad ( Equation 23 )$$

is known, and which probabilities to assign to each type (Equation 22.2), the remaining problem is designing a Huffman code for that distribution.

In order to encode a type with parameters kₗ, . . . , kₘ, a unique index I(kₗ, . . . , kₘ) may be obtained. The index I may be computed as follows:

$$I ( {k}_{1} , … , {k}_{m} ) = {\sum }_{j = 1}^{n - 2} {\sum }_{i = 0}^{{k}_{j} - 1} ( \begin{matrix}n - 1 - {\sum }_{l = 1}^{j - 1} {k}_{l} + m - j - 1 \\ m - j - 1\end{matrix} ) + {k}_{n - 1} . \qquad ( Equation 24 )$$

Equation 24 follows by induction (starting with m=2, 3, . . . ) and implements a lexicographic enumeration of types. For example,

$$\begin{matrix}I ( 0 , 0 , … , 0 , n ) = 0 , \\ I ( 0 , 0 , … , 1 , n - 1 ) = 1 , \\ … \\ I ( n , 0 , … , 0 , 0 ) = ( \begin{matrix}n + m - 1 \\ m - 1\end{matrix} ) - 1.\end{matrix}$$

With a pre-computed array of binomial coefficients, the computation of the index I by suing Equation 24 requires O(n) operations.

Type Encoding Rate: The type encoding rate refers to how efficiently a type may be encoded. From Equations 8, 9, and 16, and the above discussion, it can be ascertained that the rate of code for KT-estimated density for types (Equation 22) satisfies (under any actual distribution P):

$$L ( t , n ) = H ( t ) + {R}_{KT} ( n ) \sim H ( t ) + \frac{m - 1}{2} log n + O ( 1 ) . \qquad ( Equation 25 )$$

where H(t) is the entropy of type distribution. By expanding Equation 25 using Equation 16, the rate (or length) of code obtained is:

L(t,n)=(m−1)log n+O(1). (Equation 26)

Encoding Precision versus Rate: Based on the above observations and Equation 28, it is noted that coding of type gives an exact rate, which is proportional to the logarithm of length of the sample.

In some cases, however, it may be required to fit distribution description into a smaller number of bits. Therefore, there is a need for a mechanism for quantizing type information.

Perhaps the simplest way to accomplish this is to simply replace sample type:

$$t = [ \frac{{k}_{1}}{n} , … , \frac{{k}_{m}}{n} \text{:} {\sum }_{i} {k}_{i} = n ] \qquad ( Equation 27 )$$

with modified quantities:

$$\tilde{t} = [ \frac{{\tilde{k}}_{1}}{\tilde{n}} , … , \frac{{\tilde{k}}_{m}}{\tilde{n}} : {\sum }_{i} {\tilde{k}}_{i} = \tilde{n} ] , \qquad ( Equation 28 )$$

and with a smaller new total ñ<n. This new total ñ can be given as an input parameter, and so the task is to find quantities \tilde{k}ᵢ, such that:

$$\frac{{\tilde{k}}_{i}}{\tilde{n}} \approx \frac{{k}_{i}}{n} . \qquad ( Equation 29 )$$

### Therefore,

$${\tilde{k}}_{i} \approx {k}_{i} \frac{\tilde{n}}{n} . \qquad ( Equation 30 )$$

The whole problem can be viewed as one of scalar quantization with step size ñ/n and an extra constraint that Σ\tilde{k}ᵢ=ñ.

Type Quantization: The task of type quantizing can be solved, for example, by the following modification of Conway and Sloane's algorithm (discussed by J. H. Conway and N. J. A. Sloane, “Fast Quantizing and Decoding Algorithms for Lattice Quantizers and Codes”, IEEE Transactions on Information Theory, Vol. IT-28, No. 2, (1982)). According to one example, a set of types may be quantized according to the following algorithm.

1. Given quantities {kᵢ}, produce best unconstrained approximations:

$${\hat{k}}_{i} = ⌊ {k}_{i} \frac{\tilde{n}}{n} + \frac{1}{2} ⌋ .$$

2. Compute quantity:

$$d = {\sum }_{i} {\hat{k}}_{i} - \tilde{n}$$

a. if d=0 go to step 5.

3. Compute approximation errors:

$${δ}_{i} = {\hat{k}}_{i} - {k}_{i} \frac{\tilde{n}}{n} ,$$

and sort them such that:

−½≦δᵢ_{_{1≦δ}}ᵢ_{₂}≦ . . . ≦δᵢ_{ₘ}≦½.

4. If d>0 then decrement d values \hat{k}ᵢ_{ⱼ} with largest errors:

\hat{k}ᵢ_{ⱼ}=\hat{k}ᵢ_{ⱼ}−1, j=m−d . . . m;
otherwise (when d<0) then increment d values \hat{k}ᵢ_{ⱼ} with smallest errors:

\hat{k}ᵢ_{ⱼ}=\hat{k}ᵢ_{ⱼ}+1,i=1 . . . d.

5. Save the adjusted values as best found approximations: \tilde{k}=, i=1 . . . m;

\tilde{k}=\hat{k},i=1 . . . m.

The precision of approximations found by this algorithm satisfies:

$$\begin{matrix}{δ}^{*} ( \frac{\tilde{k}}{\tilde{n}} , \frac{k}{n} ) = {max}_{i} \vert \frac{\tilde{{k}_{i}}}{\tilde{n}} - \frac{{k}_{i}}{n} \vert \leq \frac{1}{\tilde{n}} ; \\ and & ( Equation 31 ) \\ V ( \frac{\tilde{k}}{\tilde{n}} , \frac{k}{n} ) = {\sum }_{1} \vert \frac{\tilde{{k}_{i}}}{\tilde{n}} - \frac{{k}_{i}}{n} \vert \leq \frac{m}{2 \tilde{n}} . & ( Equation 32 )\end{matrix}$$

Based on the above discussion, it is known that the rate needed to encode a type with quantized total n will be:

R(t,ñ)≦(m−1)log ñ+O(1). (Equation 33)

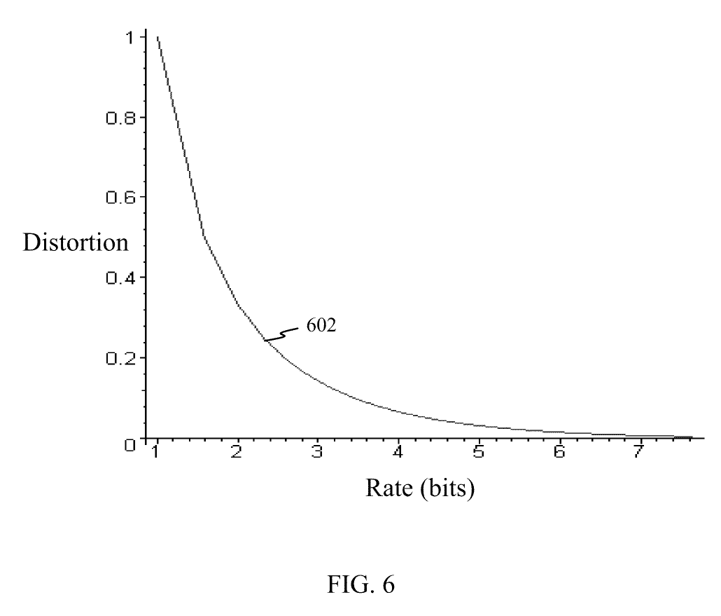

The upper bounds for both rate and distortion may be given by, for example, parametric functions of ñ. FIG. 6 illustrates a plot of a Rate versus Distortion (R-D) boundary 602 achievable by type coding (for m=2).

It can be readily shown that an approximate direct form expression for this curve is

$${δ}^{*} ( \frac{\tilde{k}}{\tilde{n}} , \frac{k}{n} ) \leq {2}^{- \frac{R}{m - 1}} . \qquad ( Equation 34 )$$

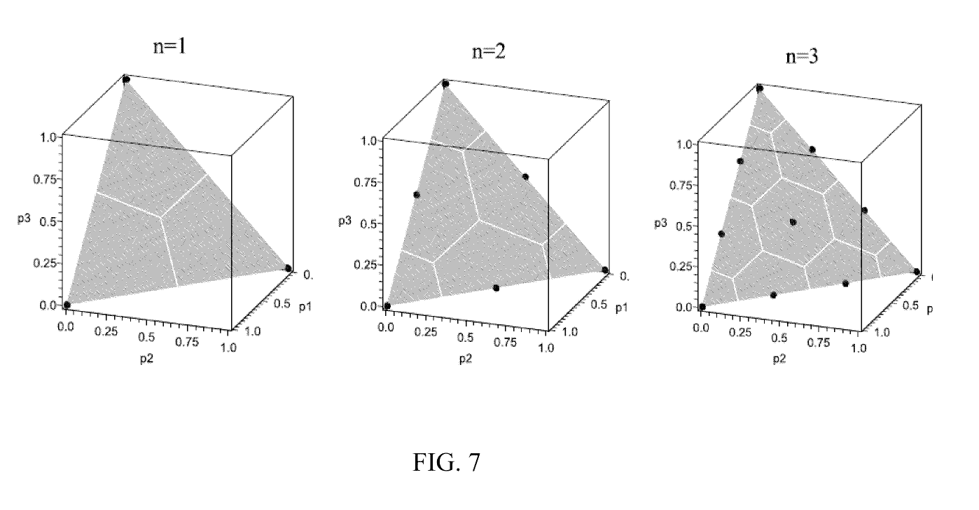

It should be noted that the quantized types essentially create a lattice over a probability space. Even very small values of parameter n (or ñ) are sufficient to fully cover it. FIG. 7 illustrate several example type lattices created for ternary histograms (e.g., Voronoi partitions for m=3 and n=1, 2, 3).

The one or more techniques, algorithms, and/or features described herein may serve to optimally encode estimated shapes of distributions. These one or more techniques may be applied to coding of distributions of keypoint descriptors, such as SIFT, SURF, GLOH, CHoG and others.

### Incremental Coding of Distributions

Note that, referring again to Equation 7, the estimated universal probability assignment to each type t may be given by

$${P}_{KT} ( n , k ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$

where

$$( \begin{matrix}n \\ {k}_{1} , … , {k}_{m}\end{matrix} )$$

is a binomial coefficient where n is the total number of samples in the probability distribution, k₁, . . . , kₘ represent a set of different samples in the probability distribution, m is the total number of different samples in the set of different samples, and π is the product operator, and Γ is the Gamma function. One problem with using this approach directly is that, for a large sample size n, the distributions are given by

$$M ( m , n ) = ( \begin{matrix}n + m - 1 \\ m - 1\end{matrix} ) = O ( {n}^{m - 1} ) . \qquad ( Equation 35 )$$

The number of possible types quickly becomes impractical even for a moderate number of samples n (e.g., with m=5 and n=20, a 10626-point distribution is created).

One approach to overcoming this coding problem is to use incremental estimation of type probabilities, coupled with an arithmetic encoder.

According to one example, where m=2 (i.e., binary case), the type of any sample w is given by a pair (k, n−k) where k is the number of 1's in the sample w and n is the total length of the sample w. Consequently, the KT-estimated distribution of types becomes:

$${P}_{KT}^{′} ( n , k ) = ( \begin{matrix}n \\ k\end{matrix} ) \frac{Γ ( k + \frac{1}{2} ) Γ ( n - k + \frac{1}{2} )}{πΓ ( n + 1 )} . \qquad ( Equation 36 )$$

Using the following property of the Gamma function

$$Γ ( x + \frac{1}{2} ) = \frac{( 2 x ) !}{{4}^{x} x !} \sqrt{π} , \qquad ( Equation 37 )$$

leads to

$$\begin{matrix}{P}_{KT}^{′} ( n , k ) = \frac{n !}{k ! ( n - k ) !} \frac{1}{π n !} \frac{( 2 k ) !}{{4}^{k} k !} \sqrt{π} \frac{( 2 ( n - k ) ) !}{{4}^{n - k} ( n - k ) !} \sqrt{π} , & ( Equation 38 ) \\ = \frac{( 2 k ) !}{{4}^{n} {( k ! )}^{2}} \frac{( 2 ( n - k ) ) !}{{( ( n - k ) ! )}^{2}} . & ( Equation 39 )\end{matrix}$$

For Equation 39, it follows that when a state where length n=0 and the number of symbols “1” is k=0 (i.e., nothing is known about the sequence), the probability is:

P′_{KT}(0,0)=1.

When the sequence length n=1 and the only symbol in the sequence is “0” (i.e., k=0), then the probability is:

$${P}_{KT}^{′} ( 1 , 0 ) = \frac{1}{2} .$$

When the sequence length n=1 and the only symbol in the sequence is “1” (i.e., k=1), then the probability is:

$${P}_{KT}^{′} ( 1 , 1 ) = \frac{1}{2} .$$

This may now be expanded for longer sequences. For instance, after processing a sequence n symbols long having k ones (symbol “1”) therein, and the next symbol is zero (symbol “0”), the probability for the sequence is given by:

$$\begin{matrix}{P}_{KT}^{′} ( n + 1 , k ) = {P}_{KT}^{′} ( n , k ) \frac{2 ( n - k + 1 ) ( 2 ( n - k ) + 1 )}{4 {( n - k + 1 )}^{2}} , \\ = {P}_{KT}^{′} ( n , k ) \frac{( 2 ( n - k ) + 1 )}{2 ( n - k + 1 )} , \\ = {P}_{KT}^{′} ( n , k ) ( \frac{n - k + \frac{1}{2}}{n - k + 1} ) ,\end{matrix} \qquad ( Equation 40 )$$

Alternatively, after processing a sequence n symbols long having k ones (symbol “1”) therein, and the next symbol is another one (symbol “1”), the probability for the sequence is given by:

$$\begin{matrix}{P}_{KT}^{′} ( n + 1 , k + 1 ) = {P}_{KT}^{′} ( n , k ) \frac{2 ( k + 1 ) ( 2 k + 1 )}{4 {( k + 1 )}^{2}} , \\ = {P}_{KT}^{′} ( n , k ) \frac{2 k + 1}{2 ( k + 1 )} , \\ = {P}_{KT}^{′} ( n , k ) \frac{k + \frac{1}{2}}{k + 1} ,\end{matrix} \qquad ( Equation 41 )$$

Combining Equations 40 and 41, the probability of distribution for a binary sequence of symbols may be given by:

$${P}_{KT}^{′} ( n + 1 , k + α ) = [ \begin{matrix}{P}_{KT}^{′} ( n , k ) \frac{k + \frac{1}{2}}{k + 1} , if α = 1 \\ {P}_{KT}^{′} ( n , k ) \frac{n - k + \frac{1}{2}}{n - k + 1} , if α = 0 ,\end{matrix} \qquad ( Equation 42 )$$

Comparing Equation 42 to the traditional recursive KT-estimate of probability of a message (not the type):

$${P}_{KT}^{′} ( n + 1 , k + α ) = [ \begin{matrix}{P}_{KT}^{′} ( n , k ) \frac{k + \frac{1}{2}}{k + 1} , if α = 1 \\ {P}_{KT}^{′} ( n , k ) \frac{n - k + \frac{1}{2}}{n + 1} , if α = 0 ,\end{matrix} \qquad ( Equation 43 )$$

it can be noticed that in the case of a message, there is one distribution (with total frequency being n), but in the case of types, the probability P′_{KT} for a type is a product of probabilities from two different distributions. That is, for the binary case of symbols 0 and 1, the probability of distribution for a type is the product of:

$$λ = \frac{k + \frac{1}{2}}{k + 1} \qquad ( Equation 44 )$$

which is the distribution associated with symbol 1, and

$$1 - λ = \frac{n - k + \frac{1}{2}}{n - k + 1} \qquad ( Equation 45 )$$

which is the distribution associated with symbol 0. Consequently, if a type for a sample w (e.g., message) is to be encoded, two sets of probability tables are needed in the binary case, for symbols 1 and 0, which may be invoked as a context while scanning the sample (message) w.

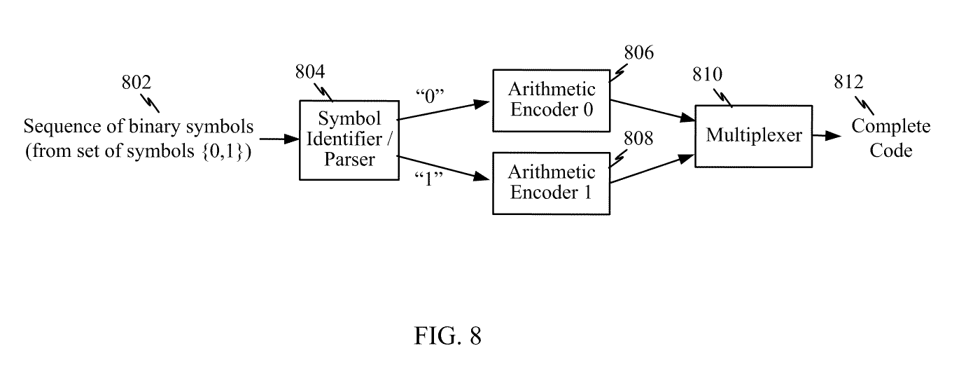

FIG. 8 is a block diagram illustrating the incremental coding of a type of a sequence for a binary set of symbols (e.g., 0 and 1). That is, the sequence of binary symbols 802 includes only symbols 0 and 1. The “type of a sequence” may be an empirical probability distribution of symbols in the sequence of symbols. A symbol identifier module 804 identifies each symbol in the sequence 802 and sends it to either a first arithmetic encoder 806, that tracks symbol 0, or a second arithmetic encoder 808, that tracks symbol 1. Arithmetic coding is a form of variable-length entropy encoding used in lossless data compression. Normally, a sequence of symbols is represented using a fixed number of bits per symbol. When a sequence is converted to arithmetic encoding, frequently-used symbols are stored with fewer bits and not-so-frequently occurring symbols are stored with more bits, resulting in fewer bits used in total. Arithmetic coding differs from other forms of entropy encoding such as Huffman coding, in that rather than separating the input into component symbols and replacing each with a code, arithmetic coding encodes the entire message into a single code. Here, the first and second arithmetic encoders 806 and 808 are adapted to perform such arithmetic coding based on the probability distribution of symbols 1's and 0's. For instance, the encoding of each successive symbol 1 may be done by the probability specified in Equation 44, while the encoding of each successive symbol 0 may be done by assigning its probability as according to Equation 45. The results (e.g., incremental codes) of the first and second arithmetic encoders 806 and 808 may then be combined by a multiplexer 810 to provide a complete code 812. In this manner, the frequency or probability distribution of symbols 0 and 1 in a sequence may be encoded incrementally (by each encoder) and the resulting incremental code for each encoder is multiplexed or concatenated to provide the complete code 812.

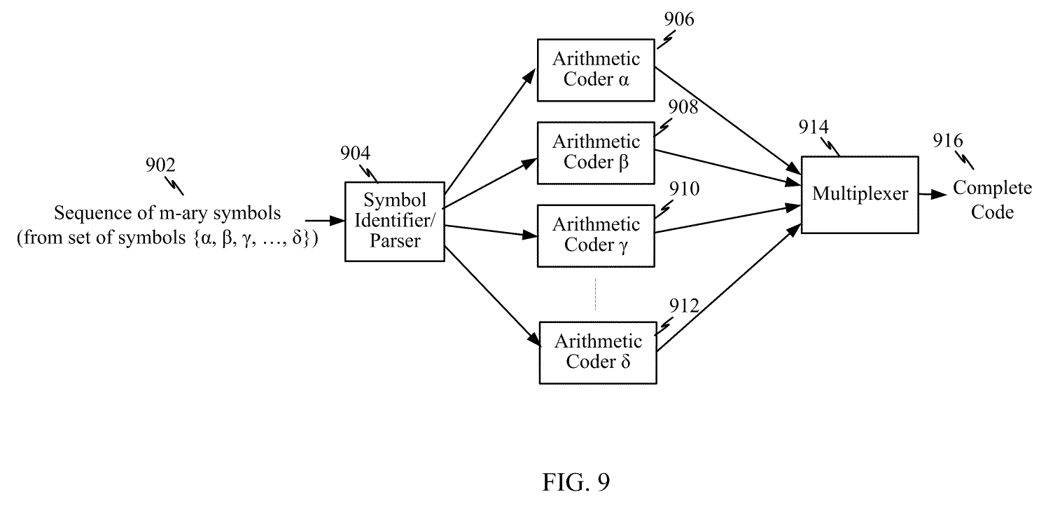

FIG. 9 is a block diagram illustrating the incremental coding of a type of a sequence including an m-ary set of symbols (e.g., α, β, γ, . . . , δ). The incremental coding illustrated in FIG. 8 for a binary set of symbols can be extended to the case where the set of symbols includes more than two symbols (e.g., m>2, m-ary case). In the m-ary case, the KT-distribution of types becomes

$$\begin{matrix}{P}_{KT} ( w ) = ξ ( k ) {P}_{KT} ( w ) {\vert}_{w ∈ W ( t )} & ( Equation 46 ) \\ = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} . & ( Equation 47 )\end{matrix}$$

By using the same technique as the binary example, the KT-probability can be given as:

$${P}_{KT}^{′} ( w α ) = {P}_{KT}^{′} ( w ) \frac{{r}_{α} ( w ) + \frac{1}{2}}{{r}_{α} ( w ) + 1} , \qquad ( Equation 48 )$$

where r_{α}(w) denotes the number of times a symbol α appears in the sequence or message w.
Encoding of a type of sequence can therefore be reduced to encoding of a system of m binary sources with estimated probabilities

$$p ( α ) = \frac{{r}_{α} ( w ) + \frac{1}{2}}{{r}_{α} ( w ) + 1} . \qquad ( Equation 49 )$$

Thus, for a sequence of m-ary symbols 902, a symbol identifier or parser 904 identifies each symbol in the sequence 902 and sends it to the corresponding arithmetic coder 906, 908, 910, or 912. This process is repeated for every symbol in the sequence so that each arithmetic coder 906, 908, 910, or 912 incrementally codes occurrences of each symbol in the sequence 902. Thus, the more frequently occurring symbols are encoded using fewer bits than less frequently occurring symbols. Each arithmetic encoder 906, 908, 910, or 912 generates an incremental code for its corresponding symbol. The incremental codes are then concatenated or multiplexed by a multiplexer 912 to provide a complete code 914. The complete code 914 is thus a compressed representation of the symbol frequency or probability distribution for the sequence 902.

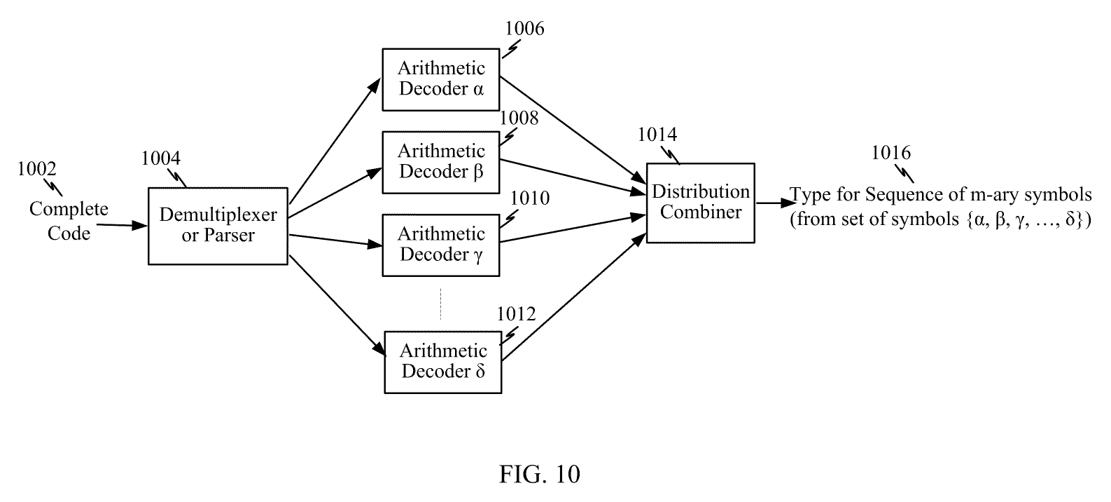

FIG. 10 is a block diagram illustrating decoding of an incrementally coded type of a sequence having an m-ary set of symbols. A complete code 1002 is received and demultiplexed, segmented, or parsed by a demultiplexer or parser 1004 to obtain a plurality of incremental codes. Each incremental code corresponds to a different symbol from a defined set of symbols. Each of a plurality of arithmetic decoders 1006, 1008, 1010, and/or 1012 may correspond to a different symbol (in the set of symbols) and is used to obtain a frequency or probability distribution for each symbol within the sequence. A distribution combiner 1014 may collect the symbol frequency or probability distribution from each arithmetic decoder and provides a type for a sequence 1016 of m-ary symbols.

### Exemplary Incremental Encoder

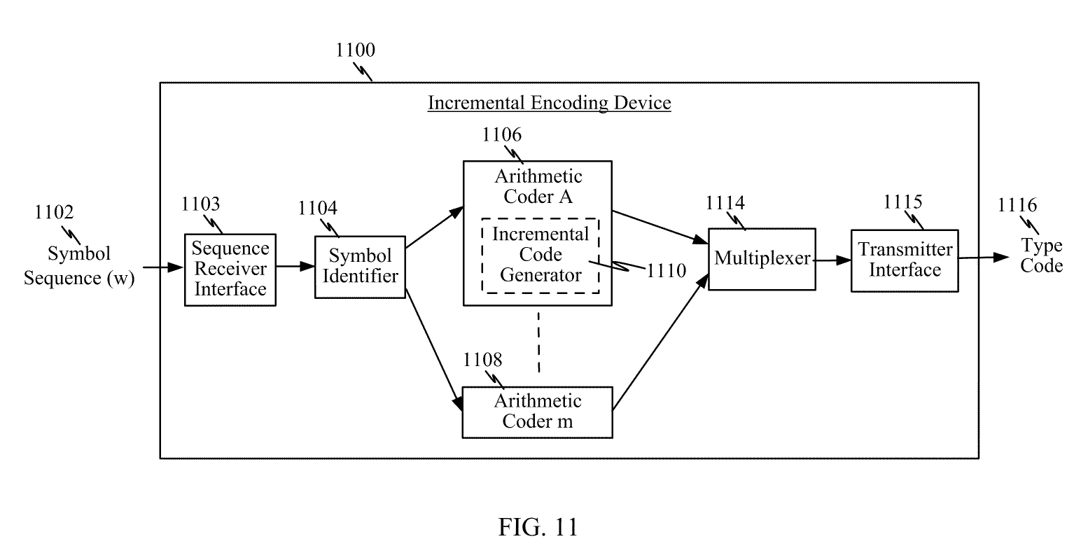

FIG. 11 is a block diagram of an exemplary encoding device for incremental encoding of a type of a sequence. The incremental encoding device 1100 may be implemented as one or more independent circuits, processors, and/or modules or it may be integrated into another circuit, processor, or module. The incremental encoding device 1100 may include a receiver interface for obtaining/receiving a sequence of symbols 1102, where each symbol is defined within a set of symbols. In various implementations, the set of symbols may include a plurality of two or more symbols. A symbol identifier 1104 may be adapted to identify each symbol in the sequence 1102. As each symbol is identified, it is sent to a corresponding arithmetic coder (encoder) from a plurality of arithmetic coders 1106 and 1108. Each arithmetic coder may correspond to a different symbol in the set of symbols. Thus, each arithmetic coder may be adapted to arithmetically code its corresponding symbol in the sequence of symbols using only previous occurrences of the same symbol in the sequence of symbols as a context (to the arithmetic coder) to generate an incremental code. For instance, the number of arithmetic coders may be equal to a number of symbols in the set of symbols. In one example, each arithmetic coder 1106 and 1108 may include an incremental code generator 1110 that may implement, for example, context-adaptive binary arithmetic coding. In one example, each arithmetic coder estimates the probability of occurrence of the next symbol as

$$\frac{{k}_{i} + \frac{1}{2}}{{k}_{i} + 1} ,$$

where kᵢ is the number of previous occurrences of the same symbol in the sequence of symbols.

Upon all symbols in the sequence being coded, each arithmetic coder 1106 and 1108 provides an incremental code to a multiplexer 1114. The multiplexer 1114 may be adapted to concatenate the incremental codes for the symbols in the set of symbols to generate a complete code 1116 representative of the type of the sequence of symbols. For example, the type of sequence may be an empirical probability distribution of symbols in the sequence of symbols. Concatenating the incremental code for each symbol in the set of symbols may be performed after all symbols in the sequence have been arithmetically coded by the plurality of arithmetic coders. The complete code 1116 may then be store and/or transmitted. In some examples, the sequence of symbols may be representative of a set of gradients for a patch around a keypoint for an image object. For instance, a transmitter interface 1115 may transmit the complete code as part of a feature descriptor.

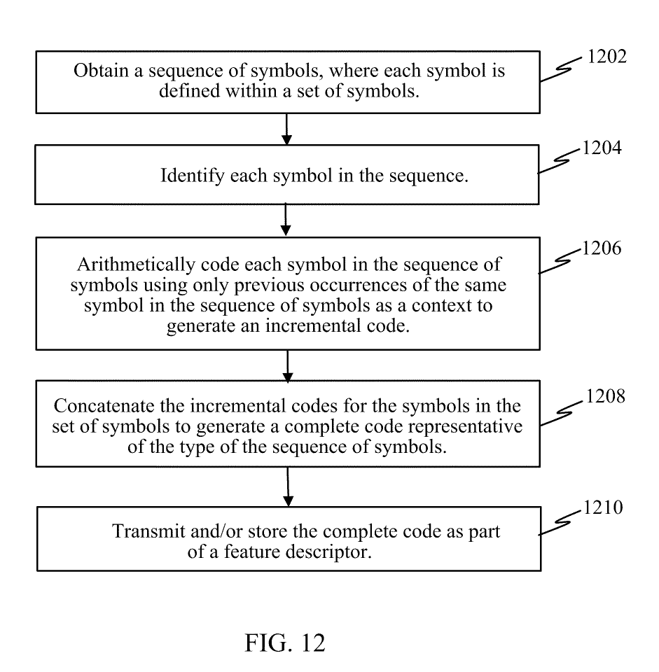

FIG. 12 illustrates an exemplary method for incremental encoding of a type of a sequence. A type of sequence may an empirical probability distribution of symbols in a sequence of symbols. A sequence of symbols is obtained, where each symbol is defined within a set of symbols 1202. The set of symbols may include a plurality of two or more symbols. For example, in a binary set, symbols “0” and “1” may be used. The sequence of symbols may comprise a plurality of symbols in any combination. In one example, the sequence of symbols may be representative of a set of gradients for a patch around a keypoint for an image object. Each symbol in the sequence in the sequence may then be identified 1204 (e.g., sequentially parsed). Each symbol in the sequence of symbols may be arithmetically coded using only previous occurrences of the same symbol in the sequence of symbols as a context (e.g., context to an arithmetic coder) to generate an incremental code 1206. Arithmetically coding each symbol may be performed separately for each symbol for the set of symbols. For instance, distinct arithmetic coders may be assigned to each symbol in the set of symbols and all occurrences of the same symbol in the sequence are coded by the same arithmetic coder. Therefore, the number of distinct arithmetic coders used may be equal to a total number of symbols in the set of symbols (e.g., where a “set of symbols” include only non-repeating symbols). In one example, the arithmetic coders may be adaptive arithmetic coders. Each arithmetic coder may estimate probability of occurrence of the next symbol as

$$\frac{{k}_{i} + \frac{1}{2}}{{k}_{i} + 1} ,$$

where kᵢ is the number of previous occurrences of the same symbol in the sequence of symbols.

The incremental codes for the symbols in the set of symbols may then be concatenated, multiplexed, and/or otherwise combined to generate a complete code representative of the type of the sequence of symbols 1208. Such “complete code” may represent, for example, a frequency distribution of symbols within the sequence of symbols.

Concatenating the incremental code for each symbol in the set of symbols may be performed after all symbols in the sequence have been arithmetically coded by the plurality of symbol-specific arithmetic coders. The complete code may subsequently be transmitted and/or stored as part of a feature descriptor 1210.

### Exemplary Mobile Device

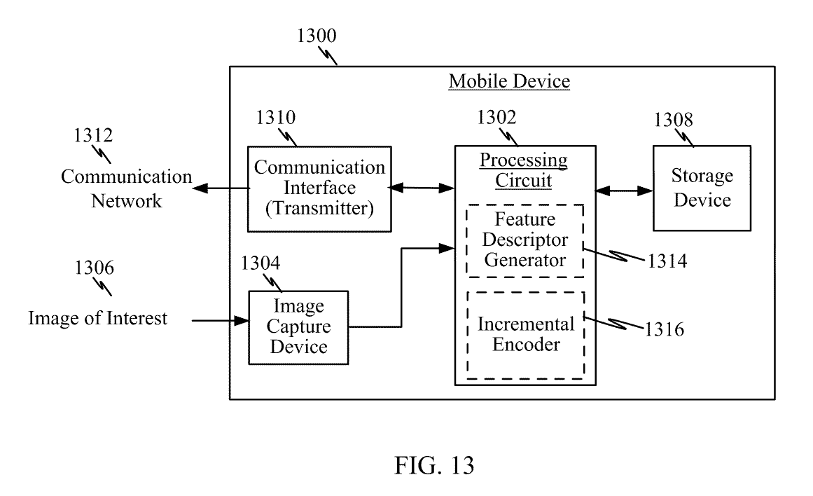

FIG. 13 is a block diagram illustrating an exemplary mobile device adapted to perform incremental probability distribution encoding. The mobile device 1300 may include a processing circuit 1002 coupled to an image capture device 1304 (e.g., digital camera), a communication interface 1310 (e.g., transmitter device) and a storage device 1308. The image capture device 1304 (e.g., digital camera) may be adapted to capture an image of interest 1306 and provides it to the processing circuit 1302. The processing circuit 1302 may be adapted to process the captured image for object recognition. For example, processing circuit may include or implement a feature descriptor generator 1314 that generates one or more feature or keypoint descriptors for the captured image. As part of generating the feature or keypoint descriptors, one or more probability distributions (e.g., gradient histograms) may be generated. The processing circuit may also include or implement an incremental probability distribution encoder 1316 that efficiently compresses the one or more type of sequences (e.g., empirical probability distribution of symbols in the sequence of symbols). For example, incremental encoder 1316 may implement one or more arithmetic coders that correspond to the different symbols to be encoded. For each instance of a symbol in a sequence of symbols to be encoded, a corresponding arithmetic coder is used to incrementally code all instances or occurrences of the same symbols. That is, as a new instance or occurrence of a symbol is obtained from the sequence of symbols, it is incrementally coded (i.e., using arithmetic coding) with previous instances of the same symbol. Once all symbols in the sequence have been coded, the resulting incremental codes for each arithmetic coder are then combined (e.g., concatenated or multiplexed) to generate a complete code. The complete code may then be used as part of a feature or keypoint descriptor.

The processing circuit 1302 may then store one or more feature descriptors in the storage device 1308 and/or may also transmit the feature descriptors over the communication interface 1310 (e.g., a wireless communication interface) through a communication network 1312 to an image matching server that uses the feature descriptors to identify an image or object therein. That is, the image matching server may compare the feature descriptors to its own database of feature descriptors to determine if any image in its database has the same feature(s).

In various examples, the probability distribution encoder 1316 may implement one or more methods described herein.

### Exemplary Incremental Decoder

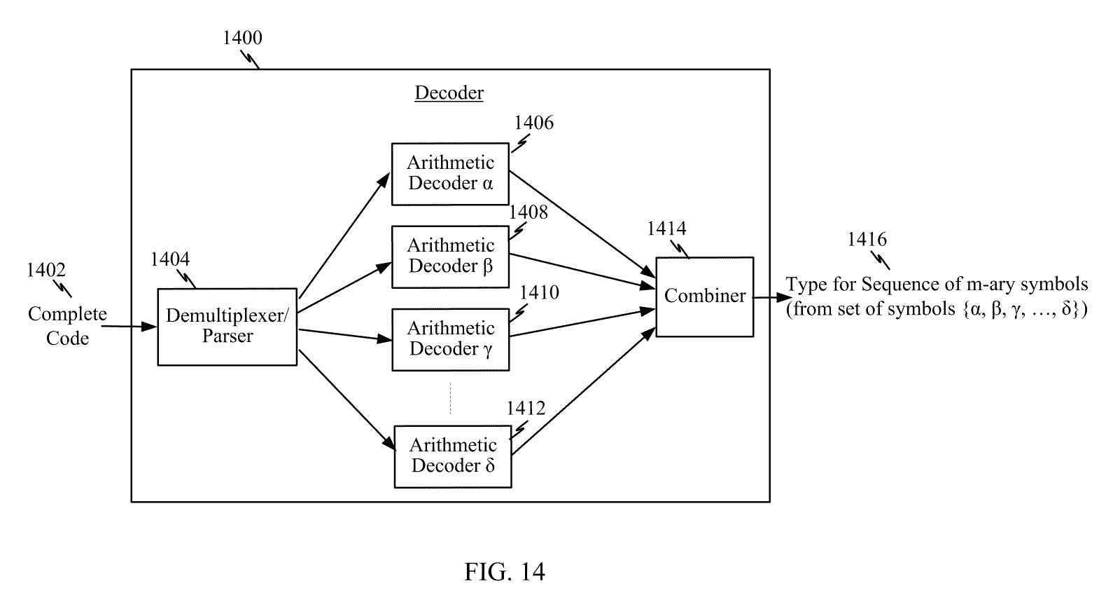

FIG. 14 is a block diagram illustrating an exemplary decoder 1400. The decoder 1400 may include a receiver for receiving a complete code representative of a type of a sequence. A parser or demultiplexer 1404 may then parse, demultiplex, and/or segment the complete code to obtain a plurality of incremental codes, each incremental code representative of a symbol in a set of symbols. The set of symbols may include a plurality of two or more symbols. In one example, each incremental code may be representative of a frequency of occurrence of the corresponding symbol within the sequence. For instance, the sequence may be representative of a set of gradients for a patch around a keypoint for an image object.

A plurality of arithmetic decoders 1406, 1406, 1410, and 1412 may then decode the incremental codes. Each arithmetic decoder may correspond to a different symbol in the set of symbols. For instance, arithmetically decoding each symbol may be performed separately for each symbol for the set of symbols, so that all occurrences of the same symbol in the sequence are decoded by the same arithmetic decoder. The number of distinct arithmetic decoders may be equal to a number of unique symbols in the set of symbols. In one example, the arithmetic decoders may be adaptive arithmetic decoders.

A combiner module 1414 may then combine the results from each arithmetic decoder and obtain a type of sequence. The plurality of arithmetic decoders may thus be adapted to decode a corresponding incremental code to obtain the type of the sequence. The “type of sequence” may be an empirical probability distribution of symbols in the sequence.

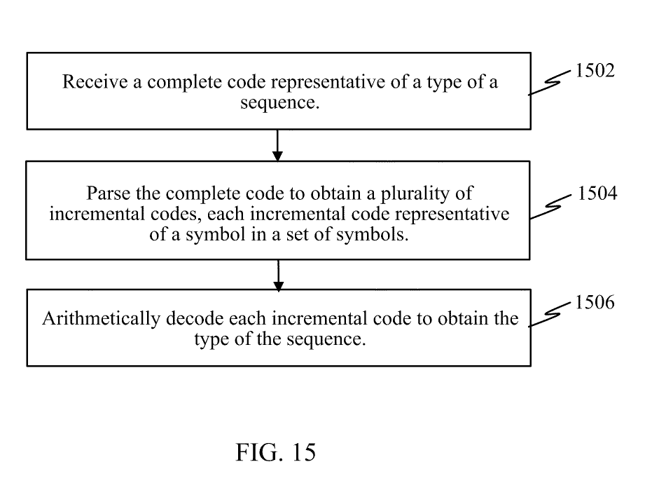

FIG. 15 illustrates an exemplary method for incremental decoding to obtain a type of a sequence. A type of sequence may be an empirical probability distribution of symbols in a sequence of symbols. A complete code representative of a type of a sequence is received 1502. The complete code is then parsed, demultiplexed, and/or segmented to obtain a plurality of incremental codes, each incremental code representative of a symbol in a set of symbols 1504. For instance, each incremental code may be representative of a frequency of occurrence of the corresponding symbol within the sequence. Arithmetically decoding each symbol may be performed separately for each symbol for the set of symbols. Thus, distinct arithmetic decoders may be assigned to each symbol in the set of symbols and all occurrences of the same symbol may be decoded by the same arithmetic decoder. Consequently, the number of distinct arithmetic decoders may be equal to a number of symbols in the set of symbols.

In one example, the arithmetic decoders are adaptive arithmetic decoders. For instance, each incremental code may be generated by an arithmetic coder that estimates probability of occurrence of the next symbol as

$$\frac{{k}_{i} + \frac{1}{2}}{{k}_{i} + 1} ,$$

where kᵢ is the number of previous occurrences of the same symbol in the sequence of symbols.

Each incremental code may then be arithmetically decoded to obtain the type of the sequence 1506. The set of symbols may include a plurality of two or more symbols. The sequence may be representative of a set of gradients for a patch around a keypoint for an image object.

### Exemplary Image Matching Device

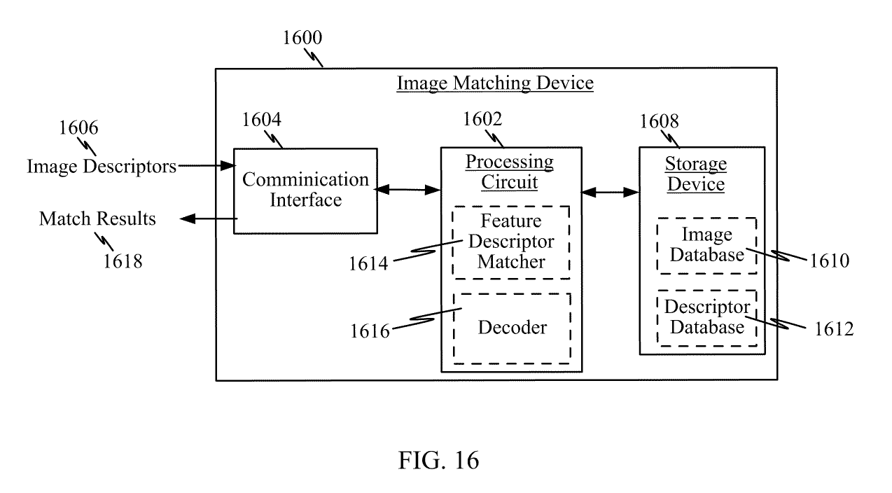

FIG. 16 is a block diagram illustrating an example of an image matching device. The image matching device 1600 may include a processing circuit 1602, coupled to a communication interface 1604 and a storage device 1608. The communication interface 1604 may be adapted to communicate over a network and receive feature descriptors 1606 for an image of interest. The processing circuit 1602 may include an image descriptor matcher 1614 that seeks to match the received image descriptors 1606 with descriptors in an image database 1612. The descriptors in the descriptor database 1612 may correspond to one or more images stored in an image database 1610. Since the received feature descriptors 1606 may include encoded histograms, a decoder 1616 may decode the received encoded histograms. The decoder 1616 may implement one or more features described herein to decode a complete code used to represent a type of sequence. Once the histograms are decoded, the feature descriptor matcher 1614 may attempt to determine if the received feature descriptors 1606 match those in the descriptor database 1612. A match result 1618 may be provided via the communication interface 1604 (e.g., to a mobile device that send the feature descriptors 1606).

Coding of types as described herein may be used in virtually any environment, application, or implementation where the shape of some sample-derived distribution is to be communicated and when nothing is known about distribution of such distributions (i.e., such that the encoding considers the worst case scenario).

A particular class of problems to which one or more of the techniques disclosed herein may be applied is coding of distributions in image feature descriptors, such as descriptors generated by CHoG, SIFT, SURF, GLOH, among others. Such feature descriptors are increasingly finding applications in real-time object recognition, 3D reconstruction, panorama stitching, robotic mapping, and/or video tracking. The histogram coding techniques disclosed herein may be applied to such feature descriptors to achieve optimal (or near optimal) lossless and/or lossy compression of histograms or equivalent types of data.

According to one exemplary implementation, an image retrieval application attempts to match a query image to one or more images in an image database. The image database may include millions of feature descriptors associated with the one or more images stored in the database. Compression of such feature descriptors by applying the one or more coding techniques described herein may save significant storage space.

According to yet another exemplary implementation, feature descriptors may be transmitted over a network. System latency may be reduced by applying the one or more coding techniques described herein to compress image features (e.g., compress feature descriptors) thereby sending fewer bits over the network.

According to yet another exemplary implementation, a mobile device may compress feature descriptors for transmission. Because bandwidth tends to be a limiting factor in wireless transmissions, compression of the feature descriptors, by applying the one or more coding techniques described herein, may reduce the amount of data transmitted over wireless channels and backhaul links in a mobile network.

Information and signals may be represented using any of a variety of different technologies and techniques. For example, data, instructions, commands, information, signals and the like that may be referenced throughout the above description may be represented by voltages, currents, electromagnetic waves, magnetic fields or particles, optical fields or particles or any combination thereof.

The various illustrative logical blocks, modules and circuits and algorithm steps described herein may be implemented or performed as electronic hardware, software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. It is noted that the configurations may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

When implemented in hardware, various examples may employ a general purpose processor, a digital signal processor (DSP), an application specific integrated circuit (ASIC), a field programmable gate array signal (FPGA) or other programmable logic device, discrete gate or transistor logic, discrete hardware components or any combination thereof designed to perform the functions described herein. A general purpose processor may be a microprocessor, but in the alternative, the processor may be any conventional processor, controller, microcontroller or state machine. A processor may also be implemented as a combination of computing devices, e.g., a combination of a DSP and a microprocessor, a plurality of microprocessors, one or more microprocessors in conjunction with a DSP core or any other such configuration.

When implemented in software, various examples may employ firmware, middleware or microcode. The program code or code segments to perform the necessary tasks may be stored in a computer-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In one or more examples herein, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media. Software may comprise a single instruction, or many instructions, and may be distributed over several different code segments, among different programs and across multiple storage media. An exemplary storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is required for proper operation of the embodiment that is being described, the order and/or use of specific steps and/or actions may be modified without departing from the scope of the claims.

One or more of the components, steps, and/or functions illustrated in the Figures may be rearranged and/or combined into a single component, step, or function or embodied in several components, steps, or functions. Additional elements, components, steps, and/or functions may also be added. The apparatus, devices, and/or components illustrated in Figures may be configured or adapted to perform one or more of the methods, features, or steps described in other Figures. The algorithms described herein may be efficiently implemented in software and/or embedded hardware for example.

It should be noted that the foregoing configurations are merely examples and are not to be construed as limiting the claims. The description of the configurations is intended to be illustrative, and not to limit the scope of the claims. As such, the present teachings can be readily applied to other types of apparatuses and many alternatives, modifications, and variations will be apparent to those skilled in the art.

What is claimed is:

1. A method for incremental encoding of a type of a sequence, comprising:
obtaining a sequence of symbols, where each symbol is defined within a set of symbols;
identifying each symbol in the sequence;
arithmetically coding each symbol in the sequence of symbols using only previous occurrences of the same symbol in the sequence of symbols as a context to generate an incremental code; and
concatenating the incremental codes for the symbols in the set of symbols to generate a complete code representative of the type of the sequence of symbols.

2. The method of claim 1, wherein the type of sequence is an empirical probability distribution of symbols in the sequence of symbols.

3. The method of claim 1, wherein arithmetically coding each symbol is performed separately for each symbol for the set of symbols.

4. The method of claim 1, wherein distinct arithmetic coders are assigned to each symbol in the set of symbols and all occurrences of the same symbol in the sequence are coded by the same arithmetic coder.

5. The method of claim 4, wherein the number of distinct arithmetic coders are equal to a number of symbols in the set of symbols.

6. The method of claim 4, wherein the arithmetic coders are adaptive arithmetic coders.

7. The method of claim 4, wherein each arithmetic coder estimates probability of occurrence of the next symbol as
$$\frac{{k}_{i} + \frac{1}{2}}{{k}_{i} + 1} ,$$
where kᵢ is the number of previous occurrences of the same symbol in the sequence of symbols.

8. The method of claim 1, wherein concatenating the incremental code for each symbol in the set of symbols is performed after all symbols in the sequence have been arithmetically coded by a plurality of symbol-specific arithmetic coders.

9. The method of claim 1, wherein the set of symbols includes a plurality of two or more symbols.

10. The method of claim 1, wherein the sequence of symbols is representative of a set of gradients for a patch around a keypoint for an image object.

11. The method of claim 1, further comprising:
transmitting the complete code as part of a feature descriptor.

12. An encoding device for incremental encoding of a type of a sequence, comprising:
a receiver interface for obtaining a sequence of symbols, where each symbol is defined within a set of symbols;
a symbol identifier adapted to identify each symbol in the sequence;
a plurality of arithmetic coders, each arithmetic coder corresponding to a different symbol in the set of symbols, each arithmetic coder adapted to arithmetically code its corresponding symbol in the sequence of symbols using only previous occurrences of the same symbol in the sequence of symbols as a context to generate an incremental code; and
a multiplexer adapted to concatenate the incremental codes for the symbols in the set of symbols to generate a complete code representative of the type of the sequence of symbols.

13. The encoding device of claim 12, wherein the type of sequence is an empirical probability distribution of symbols in the sequence of symbols.

14. The encoding device of claim 12, wherein the number of arithmetic coders are equal to a number of symbols in the set of symbols.

15. The encoding device of claim 12, wherein the arithmetic coders are adaptive arithmetic coders.

16. The encoding device of claim 15, wherein each arithmetic coder estimates probability of occurrence of the next symbol as
$$\frac{{k}_{i} + \frac{1}{2}}{{k}_{i} + 1} ,$$
where kᵢ is the number of previous occurrences of the same symbol in the sequence of symbols.

17. The encoding device of claim 12, wherein concatenating the incremental code for each symbol in the set of symbols is performed after all symbols in the sequence have been arithmetically coded by the plurality of arithmetic coders.

18. The encoding device of claim 12, wherein the set of symbols includes a plurality of two or more symbols.

19. The encoding device of claim 12, wherein the sequence of symbols is representative of a set of gradients for a patch around a keypoint for an image object.

20. The encoding device of claim 12, further comprising:
a transmitter interface for transmitting the complete code as part of a feature descriptor.

21. An encoding device for encoding of a type of a sequence, comprising:
means for obtaining a sequence of symbols, where each symbol is defined within a set of symbols;
means for identifying each symbol in the sequence;
means for arithmetically coding each symbol in the sequence of symbols using only previous occurrences of the same symbol in the sequence of symbols as a context to generate an incremental code; and
means for concatenating the incremental codes for the symbols in the set of symbols to generate a complete code representative of the type of the sequence of symbols.

22. The encoding device of claim 21, wherein the type of sequence is an empirical probability distribution of symbols in the sequence of symbols.

23. The encoding device of claim 21, further comprising:
means for transmitting the complete code as part of a feature descriptor.

24. A machine-readable medium comprising instructions operational for encoding of a type of a sequence, which when executed by a processor causes the processor to:
obtain a sequence of symbols, where each symbol is defined within a set of symbols;
identify each symbol in the sequence;
arithmetically code each symbol in the sequence of symbols using only previous occurrences of the same symbol in the sequence of symbols as a context to generate an incremental code; and
concatenate the incremental codes for the symbols in the set of symbols to generate a complete code representative of the type of the sequence of symbols.

25. The machine-readable medium of claim 24, wherein the type of sequence is an empirical probability distribution of symbols in the sequence of symbols.

26. The machine-readable medium of claim 24, wherein distinct arithmetic coders are assigned to each symbol in the set of symbols and all occurrences of the same symbol in the sequence are coded by the same arithmetic coder.

27. A method for decoding a type of a sequence, comprising:
receiving a complete code representative of a type of a sequence;
parsing the complete code to obtain a plurality of incremental codes, each incremental code representative of a symbol in a set of symbols; and
arithmetically decoding each incremental code to obtain the type of the sequence.

28. The method of claim 27, wherein the type of sequence is an empirical probability distribution of symbols in the sequence.

29. The method of claim 27, wherein each incremental code is also representative of a frequency of occurrence of the corresponding symbol within the sequence.

30. The method of claim 27, wherein arithmetically decoding each symbol is performed separately for each symbol for the set of symbols.

31. The method of claim 27, wherein distinct arithmetic decoders are assigned to each symbol in the set of symbols and all occurrences of the same symbol are decoded by the same arithmetic decoder.

32. The method of claim 31, wherein the number of distinct arithmetic decoders are equal to a number of symbols in the set of symbols.

33. The method of claim 31, wherein the arithmetic decoders are adaptive arithmetic decoders.

34. The method of claim 31, wherein each incremental code is generated by an arithmetic coder that estimates probability of occurrence of the next symbol as
$$\frac{{k}_{i} + \frac{1}{2}}{{k}_{i} + 1} ,$$
where kᵢ is the number of previous occurrences of the same symbol.

35. The method of claim 27, wherein the set of symbols includes a plurality of two or more symbols.

36. The method of claim 27, wherein the sequence is representative of a set of gradients for a patch around a keypoint for an image object.

37. The method of claim 27, wherein the complete code is received as part of a feature descriptor.

38. A decoding device, comprising
a receiver for receiving a complete code representative of a type of a sequence;
a parser for parsing the complete code to obtain a plurality of incremental codes, each incremental code representative of a symbol in a set of symbols; and
a plurality of arithmetic decoders, each arithmetic decoder corresponding to a different symbol in the set of symbols, the plurality of arithmetic decoders adapted to decode a corresponding incremental code to obtain the type of the sequence.

39. The decoding device of claim 38, wherein the type of sequence is an empirical probability distribution of symbols in the sequence.

40. The decoding device of claim 38, wherein each incremental code is also representative of a frequency of occurrence of the corresponding symbol within the sequence.

41. The decoding device of claim 38, wherein arithmetically decoding each symbol is performed separately for each symbol for the set of symbols.

42. The decoding device of claim 38, wherein all occurrences of the same symbol in the sequence are decoded by the same arithmetic decoder.

43. The decoding device of claim 38, wherein the number of distinct arithmetic decoders are equal to a number of symbols in the set of symbols.

44. The decoding device of claim 38, wherein the arithmetic decoders are adaptive arithmetic decoders.

45. The decoding device of claim 38, wherein each incremental code is generated by an arithmetic coder that estimates probability of occurrence of the next symbol as
$$\frac{{k}_{i} + \frac{1}{2}}{{k}_{i} + 1} ,$$
where kᵢ is the number of previous occurrences of the same symbol.

46. The decoding device of claim 38, wherein the set of symbols includes a plurality of two or more symbols.

47. The decoding device of claim 38, wherein the sequence is representative of a set of gradients for a patch around a keypoint for an image object.

48. A decoding device, comprising
means for receiving a complete code representative of a type of a sequence;
means for parsing the complete code to obtain a plurality of incremental codes, each incremental code representative of a symbol in a set of symbols; and
means for arithmetically decoding each incremental code to obtain the type of the sequence.

49. The decoding device of claim 48, wherein the type of sequence is an empirical probability distribution of symbols in the sequence.

50. The decoding device of claim 48, wherein each incremental code is also representative of a frequency of occurrence of the corresponding symbol within the sequence.

51. A machine-readable medium comprising instructions operational for decoding a type of a sequence, which when executed by a processor causes the processor to:
receive a complete code representative of a type of a sequence;
parse the complete code to obtain a plurality of incremental codes, each incremental code representative of a symbol in a set of symbols; and
arithmetically decode each incremental code to obtain the type of the sequence.

52. The machine-readable medium of claim 51, wherein the type of sequence is an empirical probability distribution of symbols in the sequence.

53. The machine-readable medium of claim 51, wherein distinct arithmetic decoders are assigned to each symbol in the set of symbols and all occurrences of the same symbol in the sequence are decoded by the same arithmetic decoder.
